(19) United States
(12) Patent Application Publication
(10) Pub. No.: US 2026/0334292 A1
(43) Pub. Date: Oct. 22, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Yung-Ta LI, Taichung City (TW); Chien-Yi CHIA, Taichung City (TW)

(73) Assignee: SILICONWARE PRECISION INDUSTRIES CO., LTD., Taichung City (TW)

(21) Appl. No.: 19/377,493

(22) Filed: Nov. 3, 2025

(30) Foreign Application Priority Data
Apr. 17, 2025 (TW) 114114595

(51) Int. Cl. H01L 23/31; H01L 21/48; H01L 21/56; H01L 23/00; H01L 23/48; H01L 23/538; H01L 25/16

(52) U.S. Cl. CPC H10W 74/121; H10W 20/20; H10W 70/099; H10W 70/611; H10W 74/01; H10W 74/114; H10W 90/00; H10W 90/401; H10W 74/15; H10W 90/724; H10W 90/734

(57) ABSTRACT

Provided are an electronic package and a manufacturing method of the electronic package. An electronic component and an intermediary component are disposed on one side of a circuit structure, and a plurality of functional components are disposed on the other side of the circuit structure. The electronic component and the intermediary component serve as bridging components to electrically connect the plurality of functional components. A first passivation layer and a second passivation layer are formed on the electronic component and the intermediary component, respectively, and a plurality of conductive vias of the intermediary component are exposed from the second passivation layer, so that a plurality of conductive components can be placed on the first passivation layer and the second passivation layer and electrically connected to the plurality of conductive vias, thereby obviating the need to form conductive bumps on the plurality of conductive vias and reducing manufacturing costs.

### BACKGROUND

### 1. Technical Field

The present disclosure relates to a semiconductor packaging technology, and more particularly, to an electronic package with enhanced reliability and a manufacturing method thereof.

### 2. Description of Related Art

High performance computing (HPC) technology is becoming more and more important and widespread in today's applications, for example, in medical fields such as cancer drug development, or in autonomous vehicles where automatic sensing and detection computations are required. In these fields, the devices typically employ a fan-out packaging (FO PKG) structure. To this end, the industry has developed various advanced packaging process technologies such as fan-out multi-chip module (FOMCM) and fan-out embedded bridge die (FOEB) structures to meet design requirements for multi-chip integration, high circuit layer counts, large fan-out dimensions, and efficient heat dissipation.

FIG. 1A to FIG. 1D are schematic cross-sectional views illustrating a conventional method for manufacturing a fan-out embedded bridge structure.

As shown in FIG. 1A, a semiconductor chip 10 is provided. The semiconductor chip 10 has a first side 10a and a second side 10b opposite to the first side 10a. A plurality of first conductive bumps 11 are formed on the first side 10a, and a plurality of conductive vias 100 are formed in the semiconductor chip 10, such that the plurality of conductive vias 100 are electrically connected to the plurality of first conductive bumps 11. The first conductive bumps 11 are, for example, metal pillars such as copper pillars.

As shown in FIG. 1B, the second side 10b is thinned (for example, by a grinding process), such that the plurality of conductive vias 100 are exposed from the second side 10b. Then, a conductive circuit 13 is formed on the second side 10b of the semiconductor chip 10, and a plurality of second conductive bumps 12 are formed on the conductive circuit 13, wherein the conductive circuit 13 is electrically connected to the plurality of conductive vias 100, such that the plurality of second conductive bumps 12 can be electrically connected to the plurality of first conductive bumps 11 via the conductive circuit 13 and the plurality of conductive vias 100. Each of the second conductive bumps 12 includes, for example, a copper pillar and a solder material.

A shown in FIG. 1C, a carrier 140 is provided. A circuit layer 141 and a plurality of conductive pillars 142 are arranged on the carrier 140. The semiconductor chip 10 is placed on the circuit layer 141 via the plurality of second conductive bumps 12. The carrier 140 is, for example, a board made of semiconductor material (such as silicon or glass).

As shown in FIG. 1D, an encapsulation layer 15 is formed to encapsulate the semiconductor chip 10 and the conductive pillars 142. Then, a circuit structure 16 is formed on the encapsulation layer 15, followed by the mounting of a plurality of electronic components 17 on the circuit structure 16. Next, a packaging layer 18 is formed to encapsulate the electronic components 17. Afterward, the carrier 140 is removed, and a plurality of conductive components 19 are formed on the circuit layer 141.

However, in the aforementioned manufacturing method, it is necessary to form second conductive bumps (μ-bumps) on the back side of the semiconductor chip containing conductive silicon vias. This not only incurs high manufacturing costs but also requires subsequent bonding of the semiconductor chip via flip-chip processes onto the circuit layer on the surface of the carrier, which in itself is another expense. Moreover, the above complicated process leads to reduced yield, low throughput, and high overall cost.

Therefore, how to overcome the aforementioned problems of the prior art has become an urgent issue to be resolved.

### SUMMARY

In view of the aforementioned shortcomings of the prior art, the present disclosure provides an electronic package, which comprises: a circuit structure having a first side and a second side opposite to the first side; an electronic component disposed on the first side of the circuit structure; an intermediary component disposed on the first side of the circuit structure and having a plurality of conductive vias; a first passivation layer formed on the electronic component; a second passivation layer formed on the intermediary component, wherein a top surface of each of the plurality of conductive vias is exposed from the second passivation layer; an encapsulation layer having a first surface and a second surface opposite to the first surface and formed on the first side of the circuit structure via the second surface, wherein the encapsulation layer encapsulates the electronic component, the intermediary component, the first passivation layer, and the second passivation layer, wherein the first passivation layer, the second passivation layer, and the top surface of each of the plurality of conductive vias are exposed from the first surface; and a plurality of functional components disposed on the second side of the circuit structure, wherein the plurality of functional components are electrically bridged via the electronic component and/or the intermediary component.

The present disclosure also provides a method of manufacturing an electronic package. The method comprises: providing an electronic module, and the electronic module comprising: a circuit structure having a first side and a second side opposite to the first side; an electronic component disposed on the first side of the circuit structure; an intermediary component disposed on the first side of the circuit structure and having a plurality of conductive vias; an encapsulation layer having a first surface and a second surface opposite to the first surface and formed on the first side of the circuit structure via the second surface to encapsulate the electronic component and the intermediary component; and a plurality of functional components disposed on the second side of the circuit structure, wherein the plurality of functional components are electrically bridged via the electronic component and/or the intermediary component; performing a thinning process on the electronic component and the intermediary component, wherein the electronic component and the intermediary component are recessed with respect to the first surface of the encapsulation layer to form a first concave portion and a second concave portion, respectively, and the plurality of conductive vias protrude from the second concave portion; and forming a first passivation layer and a second passivation layer in the first concave portion and the second concave portion, respectively, wherein the first passivation layer, the second passivation layer, and a top surface of each of the plurality of conductive vias are exposed from the first surface.

In the aforementioned method, the thinning process comprises removing a portion of a material of the electronic component and a portion of a material of the intermediary component, by a wet etching process to form the first concave portion and the second concave portion, respectively.

In the aforementioned method, the first passivation layer and the second passivation layer are formed by filling the first concave portion and the second concave portion with a liquid adhesive to cover the electronic component and the intermediary component.

The aforementioned method further comprises: performing a planarization process to remove a portion of the first passivation layer, a portion of the second passivation layer, and a portion of the encapsulation layer, wherein the first passivation layer, the second passivation layer, and the top surface of each of the plurality of conductive vias are flush with the first surface of the encapsulation layer.

In the aforementioned method, the electronic module further comprises a plurality of conductive pillars formed on the first side of the circuit structure and encapsulated by the encapsulation layer, and a top surface of each of the plurality of conductive pillars is exposed from the first surface.

In the aforementioned method, the electronic module further comprises a packaging layer formed on the second side of the circuit structure to encapsulate the plurality of functional components.

The aforementioned method further comprises: forming a plurality of conductive components on the first surface of the encapsulation layer, the first passivation layer, and the second passivation layer, wherein the plurality of conductive components are electrically connected to the plurality of conductive vias.

The aforementioned method further comprises: forming a wiring layer on the first surface of the encapsulation layer, the first passivation layer, and the second passivation layer; and forming a plurality of conductive components on the wiring layer.

In the aforementioned electronic package and method, the electronic component has an active surface and an inactive surface opposite to the active surface, and the electronic component is electrically connected to the circuit structure with the active surface of the electronic component facing the first side of the circuit structure.

In the aforementioned electronic package and method, the intermediary component is electrically connected to the circuit structure via the plurality of conductive vias.

In the aforementioned electronic package and method, the plurality of functional components are electrically connected to the circuit structure via a plurality of conductive bumps.

It can be seen from the above that, in the electronic package and the manufacturing method thereof of the present disclosure, the electronic component and the intermediary component are disposed on one side of the circuit structure, the plurality of functional components are disposed on the other side of the circuit structure, and the electronic component and the intermediary component can serve as bridging components to electrically connect the plurality of functional components. Moreover, the first passivation layer and the second passivation layer are formed on the electronic component and the intermediary component, respectively, and the plurality of conductive vias of the intermediary component are exposed from the second passivation layer. This allows the plurality of conductive components to be placed on the encapsulation layer and on the first passivation layer and the second passivation layer, and to be electrically connected to the plurality of conductive vias. Therefore, the conventional need to form conductive bumps on the conductive vias and the requirement for a glass carrier are avoided, thereby reducing manufacturing costs, simplifying the process, and improving productivity and yield.

### BRIEF DESCRIPTION OF THE DRAWINGS

FIG. 1A to FIG. 1D are schematic cross-sectional views illustrating a conventional method for manufacturing a fan-out embedded bridge structure.

FIG. 2A to FIG. 2D are schematic cross-sectional views illustrating a method for manufacturing an electronic package according to the present disclosure.

FIG. 3 is a schematic cross-sectional view of an electronic package according to another embodiment of the present disclosure.

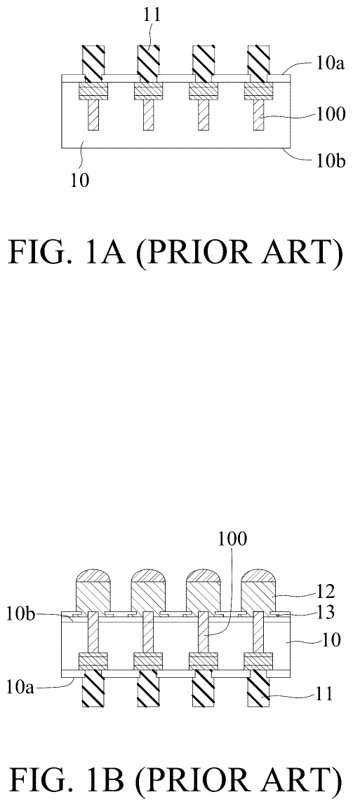

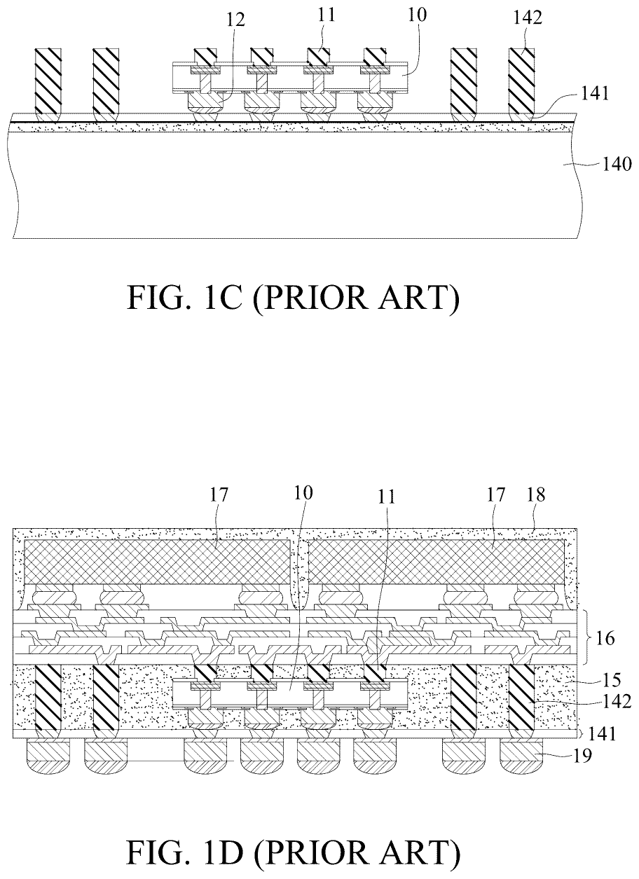

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

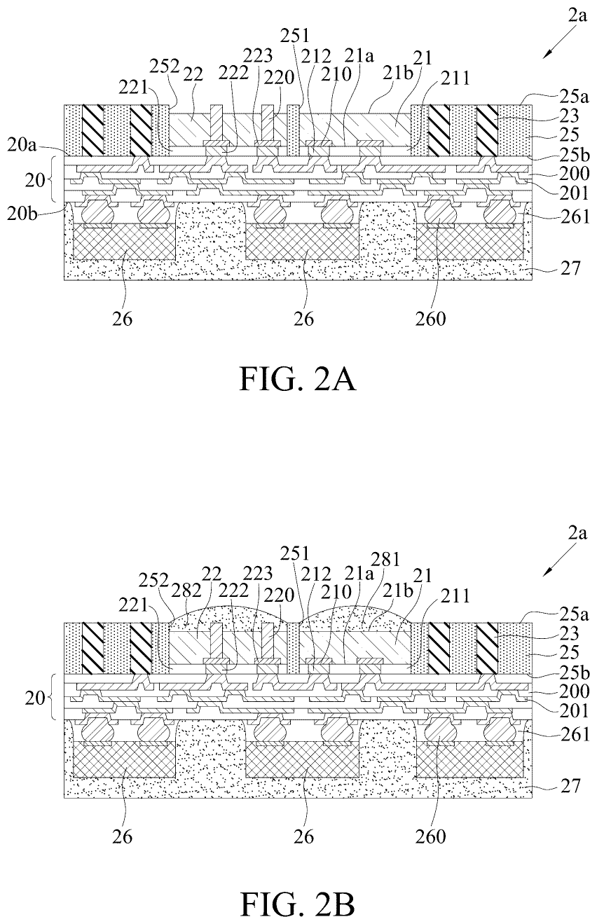

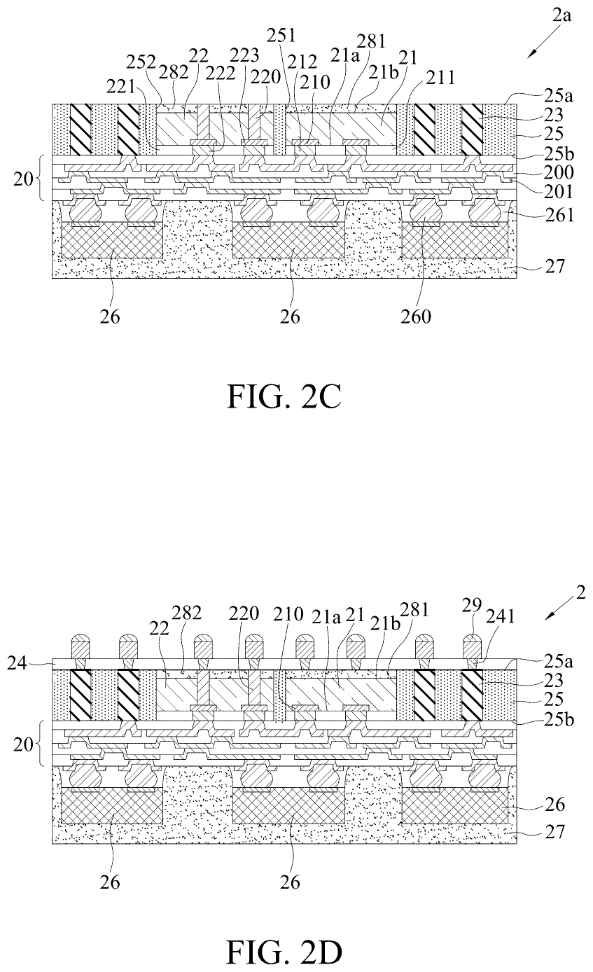

FIG. 2A to FIG. 2D are schematic cross-sectional views illustrating a method for manufacturing an electronic package 2 according to the present disclosure.

As shown in FIG. 2A, an electronic module 2a is provided, and the electronic module 2a comprises: an encapsulation layer 25, at least one electronic component 21, at least one intermediary component 22, a plurality of conductive pillars 23, a circuit structure 20, and a plurality of functional components 26.

The encapsulation layer 25 has a first surface 25a and a second surface 25b opposite to the first surface 25a. In one embodiment, the encapsulation layer 25 is made of an insulating material, for example, polyimide (PI), dry film, or an encapsulant/molding compound such as epoxy resin. For example, the encapsulation layer 25 can be formed by liquid dispensing, injection coating, lamination, or compression molding, among other techniques.

The electronic component 21 is embedded in the encapsulation layer 25. The electronic component 21 is an active component, a passive component, or a combination of the active component and the passive component. The active component is, for example, a semiconductor chip. The passive component is, for example, a resistor, a capacitor, or an inductor. In one embodiment, the electronic component 21 is a semiconductor chip and has an active surface 21a and an inactive surface 21b opposite to the active surface 21a, with the active surface 21a facing the second surface 25b and having a plurality of electrode pads 210 that bond to and electrically connect with a plurality of conductors 212, and the conductors 212 are encapsulated by a protective film 211. The conductors 212 are in the form of conductive lines, spherical solder balls, metal pillars (such as copper pillars or solder bumps), or stud-shaped conductive elements formed by a wire bonding machine.

The intermediary component 22 is made of a semiconductor material such as a silicon-based substrate and is embedded in the encapsulation layer 25. The intermediary component 22 has a plurality of conductive vias 220, such as conductive through-silicon vias (TSVs). In one embodiment, an end surface of each of the conductive vias 220 on one side of the intermediary component 22 has a contact 223 to bond with and electrically connect to a plurality of conductors 222, and the conductors 222 are encapsulated by a protective film 221. The conductors 222 are in the form of conductive lines, spherical solder balls, metal pillars (such as copper pillars or solder bumps), or stud-shaped conductive elements formed by a wire bonding machine. It should be understood that the conductive vias 220 can exhibit various configurations, such as having an insulating material covering the periphery, without being limited to a specific embodiment.

The plurality of conductive pillars 23 are embedded in the encapsulation layer 25, and the plurality of conductive pillars 23 are made of a metal material such as copper or a solder material. In one embodiment, an end surface of each of the plurality of conductive pillars 23 is exposed from the first surface 25a of the encapsulation layer 25.

The circuit structure 20 has a first side 20a and a second side 20b opposite to the first side 20a. The circuit structure 20 is disposed on the second surface 25b of the encapsulation layer 25 via the first side 20a and is electrically connected to the conductive pillars 23 as well as to the electronic component 21 and the intermediary component 22. In one embodiment, the circuit structure 20 comprises a plurality of dielectric layers 200 and a plurality of circuit layers 201 according to redistribution layer (RDL) specifications; alternatively, the circuit structure 20 may comprise a single dielectric layer 200 and a single circuit layer 201. Furthermore, the circuit layer 201 is made of copper, and the dielectric layer 200 is made of polybenzoxazole (PBO), polyimide (PI), prepreg (PP), or other dielectric materials.

The plurality of functional components 26 are disposed on the second side 20b of the circuit structure 20 and are electrically connected to the circuit layer 201, so that the encapsulation layer 25, the conductive pillars 23, the electronic component 21, and the intermediary component 22 are disposed on one side of the circuit structure 20, while the functional components 26 are disposed on the other side of the circuit structure 20. Each of the functional components 26 is an active component, a passive component, or a combination of the active component and the passive component. The active component is, for example, a semiconductor chip. The passive component is, for example, a resistor, a capacitor, or an inductor. In one embodiment, each of the functional components 26 is a semiconductor chip such as a graphics processing unit (GPU) or a high bandwidth memory (HBM) that is electrically connected to the circuit layer 201 via a flip-chip process using a plurality of conductive bumps 260, with the conductive bumps 260 subsequently encapsulated by an underfill 261.

The electronic component 21 and/or the intermediary component 22 can be used as a bridging component (a bridge die), such that the electronic component 21 and/or the intermediary component 22 are electrically connected to the circuit layer 201 of the circuit structure 20 via the conductors 212, 222 to electrically bridge the plurality of functional components 26.

In addition, a packaging layer 27 can be formed on the outermost side of the circuit structure 20 to encapsulate the plurality of functional components 26 and the underfill 261. If the packaging layer 27 encapsulates the conductive bumps 260, then there is no need to form the underfill 261. The packaging layer 27 is made of an insulating material, for example, polyimide (PI), dry film, or an encapsulant/molding compound such as epoxy resin, and the packaging layer 27 can be formed by lamination or molding. It should be understood that the material of the encapsulation layer 25 and the material of the packaging layer 27 can be the same or different. Furthermore, the packaging layer 27 can cover the top surface of each of the functional components 26; alternatively, the outer surface of the packaging layer 27 can be flush with the top surface of each of the functional components 26 depending on requirements, such that the top surface of each of the functional components 26 is exposed from the packaging layer 27.

Then, a thinning process is performed on the electronic component 21 and the intermediary component 22. For example, by using a wet etch process to remove a portion of the material from the inactive surface 21b of the electronic component 21 and a portion of the material of the intermediary component 22, the conductive vias 220 are exposed from the intermediary component 22, and the electronic component 21, the intermediary component 22, and the conductive vias 220 are exposed from the first surface 25a of the encapsulation layer 25. In other words, the electronic component 21 and the intermediary component 22 are recessed with respect to the first surface 25a of the encapsulation layer 25, thereby respectively forming a first concave portion 251 and a second concave portion 252 and causing the plurality of conductive vias 220 to protrude from the second concave portion 252. Furthermore, the depth of the first concave portion 251 and the depth of the second concave portion 252 can be the same or different, that is, the extent of thinning for the electronic component 21 and the intermediary component 22 may be the same or different, resulting in the electronic component 21 and the intermediary component 22 of the same or different thickness after the thinning process.

As shown in FIG. 2B, a first passivation layer 281 and a second passivation layer 282 are formed on the electronic component 21 and the intermediary component 22, respectively. For example, by filling the first concave portion 251 and the second concave portion 252 with liquid adhesive (such as an underfill or a non-conductive adhesive), the first passivation layer 281 and the second passivation layer 282 are formed to cover the electronic component 21, the intermediary component 22, and the conductive vias 220.

As shown in FIG. 2C, a planarization process is performed to remove a portion of the first passivation layer 281 on the electronic component 21, a portion of the second passivation layer 282 on the intermediary component 22, a portion of the material on the first surface 25a of the encapsulation layer 25, and a portion of the material of the conductive pillars 23, so that the outer surface of the second passivation layer 282 on the intermediary component 22, the end surface of each of the conductive vias 220, the outer surface of the first passivation layer 281 on the electronic component 21, the first surface 25a of the encapsulation layer 25, and the end surface of each of the conductive pillars 23 become flush. For example, the planarization process may be implemented using grinding.

As shown in FIG. 2D, a plurality of conductive components 29 are formed on the first surface 25a of the encapsulation layer 25 as well as on the first passivation layer 281 and the second passivation layer 282, with the plurality of conductive components 29 being electrically connected to the plurality of conductive pillars 23 and the plurality of conductive vias 220, thereby forming the electronic package 2.

In one embodiment, the conductive components 29 are solder balls or metal bumps such as copper bumps. For example, the conductive components 29 are C4-type solder balls (C4 stands for Controlled Collapse Chip Connection), so that the electronic package 2 is connected to an electronic device (not shown) such as a circuit board via the conductive components 29. Furthermore, a protective layer 24 may first be formed on the first surface 25a of the encapsulation layer 25, and a plurality of conductive elements 241 are formed in the protective layer 24 to bond with the plurality of conductive components 29, wherein the plurality of conductive elements 241 are erected on the first passivation layer 281, the second passivation layer 282, the plurality of conductive pillars 23, and the plurality of conductive vias 220 to electrically connect the plurality of conductive pillars 23 and the plurality of conductive vias 220. The conductive elements 241 are, for example, conductive blind vias or conductive blocks, and the conductive elements 241 are made of copper metal.

In the present disclosure, the electronic component 21 and the intermediary component 22 are disposed on one side of the circuit structure 20, the plurality of functional components 26 are disposed on the other side of the circuit structure 20, and the electronic component 21 and the intermediary component 22 can serve as bridging components to electrically connect the plurality of functional components 26. Moreover, the first passivation layer 281 and the second passivation layer 282 are formed on the electronic component 21 and the intermediary component 22, respectively, and the plurality of conductive vias 220 of the intermediary component 22 are exposed from the second passivation layer 282. This allows the plurality of conductive components 29 to be placed on the encapsulation layer 25 and on the first passivation layer 281 and the second passivation layer 282, and to be electrically connected to the plurality of conductive vias 220. Therefore, the conventional need to form conductive bumps on the conductive vias and the requirement for a glass carrier are avoided, thereby reducing manufacturing costs, simplifying the process, and improving productivity and yield. In addition, the first passivation layer 281 on the inactive surface 21b of the electronic component 21 can prevent electrical shorts caused by the placement of the conductive components 29, ensuring that the electronic component 21 functions properly.

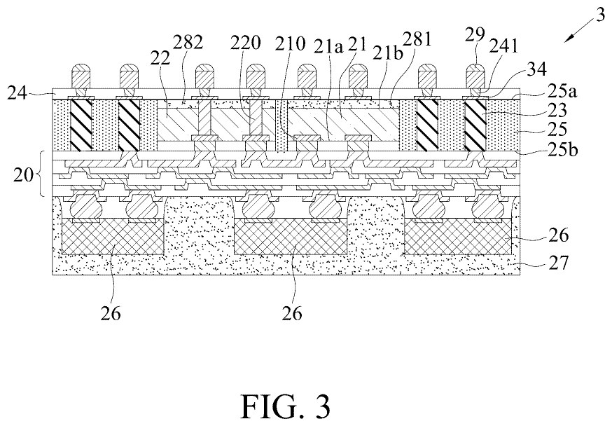

Referring to FIG. 3, in an embodiment of an electronic package 3, a wiring layer 34 may be formed on the first surface 25a of the encapsulation layer 25, on the first passivation layer 281, and on the second passivation layer 282, so that the wiring layer 34 is electrically connected to the plurality of conductive pillars 23 as well as the plurality of conductive vias 220 of the intermediary component 22. Then, the plurality of conductive elements 241 are formed on the wiring layer 34 for connecting the plurality of conductive components 29, so that the plurality of conductive components 29 are electrically connected to the plurality of conductive pillars 23 and the plurality of conductive vias 220.

The present disclosure further provides an electronic package 2, 3, which comprises: a circuit structure 20 having a first side 20a and a second side 20b opposite to the first side 20a; an electronic component 21 disposed on the first side 20a of the circuit structure 20; an intermediary component 22 disposed on the first side 20a of the circuit structure 20 and having a plurality of conductive vias 220; a first passivation layer 281 formed on the electronic component 21; a second passivation layer 282 formed on the intermediary component 22, wherein a top surface of each of the plurality of conductive vias 220 is exposed from the second passivation layer 282; an encapsulation layer 25 having a first surface 25a and a second surface 25b opposite to the first surface 25a and formed on the first side 20a of the circuit structure 20 via the second surface 25b, wherein the encapsulation layer 25 encapsulates the electronic component 21, the intermediary component 22, the first passivation layer 281, and the second passivation layer 282, wherein the first passivation layer 281, the second passivation layer 282, and the top surface of each of the plurality of conductive vias 220 are exposed from the first surface 25a; and a plurality of functional components 26 disposed on the second side 20b of the circuit structure 20, wherein the plurality of functional components 26 are electrically bridged via the electronic component 21 and/or the intermediary component 22.

In one embodiment, the electronic package 2, 3 further comprises: a plurality of conductive pillars 23 formed on the first side 20a of the circuit structure 20 and encapsulated by the encapsulation layer 25, wherein a top surface of each of the plurality of conductive pillars 23 is exposed from the first surface 25a.

In one embodiment, the electronic package 2, 3 further comprises: a packaging layer 27 formed on the second side 20b of the circuit structure 20 and encapsulating the plurality of functional components 26.

In one embodiment, the electronic package 2, 3 further comprises: a plurality of conductive components 29 disposed on the first surface 25a of the encapsulation layer 25 as well as on the first passivation layer 281 and the second passivation layer 282, wherein the plurality of conductive components 29 are electrically connected to the plurality of conductive vias 220. Furthermore, the electronic package 3 further comprises a wiring layer 34 formed on the first surface 25a of the encapsulation layer 25 as well as on the first passivation layer 281 and the second passivation layer 282, wherein the plurality of conductive components 29 are disposed on the wiring layer 34.

In one embodiment, the electronic component 21 has an active surface 21a and an inactive surface 21b opposite to the active surface 21a, wherein the electronic component 21 is electrically connected to the circuit structure 20 with the active surface 21a of the electronic component 21 facing the first side 20a of the circuit structure 20. In addition, the intermediary component 22 is electrically connected to the circuit structure 20 via the plurality of conductive vias 220.

To sum up, in the electronic package and the manufacturing method thereof of the present disclosure, the electronic component and the intermediary component are disposed on one side of the circuit structure, the plurality of functional components are disposed on the other side of the circuit structure, and the electronic component and the intermediary component can serve as bridging components to electrically connect the plurality of functional components. Moreover, the first passivation layer and the second passivation layer are formed on the electronic component and the intermediary component, respectively, and the plurality of conductive vias of the intermediary component are exposed from the second passivation layer. This allows the plurality of conductive components to be placed on the encapsulation layer and on the first passivation layer and the second passivation layer, and to be electrically connected to the plurality of conductive vias. Therefore, the conventional need to form conductive bumps on the conductive vias and the requirement for a glass carrier are avoided, thereby reducing manufacturing costs, simplifying the process, and improving productivity and yield. In addition, the first passivation layer on the inactive surface of the electronic component can prevent electrical shorts caused by the placement of the conductive components, ensuring that the electronic component functions properly. Moreover, by forming the first passivation layer and the second passivation layer on the electronic component and the intermediary component, respectively, the present disclosure can accommodate different thicknesses of the electronic component and the intermediary component, increasing the design flexibility of electronic products. Furthermore, the electronic package of the present disclosure can be manufactured using existing semiconductor packaging processes without the need to develop special processes or purchase special equipment, thereby addressing current industry technical problems.

The above embodiments are for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a circuit structure having a first side and a second side opposite to the first side;
an electronic component disposed on the first side of the circuit structure;
an intermediary component disposed on the first side of the circuit structure and having a plurality of conductive vias;
a first passivation layer formed on the electronic component;
a second passivation layer formed on the intermediary component, wherein a top surface of each of the plurality of conductive vias is exposed from the second passivation layer;
an encapsulation layer having a first surface and a second surface opposite to the first surface and formed on the first side of the circuit structure via the second surface, wherein the encapsulation layer encapsulates the electronic component, the intermediary component, the first passivation layer, and the second passivation layer, wherein the first passivation layer, the second passivation layer, and the top surface of each of the plurality of conductive vias are exposed from the first surface; and
a plurality of functional components disposed on the second side of the circuit structure, wherein the plurality of functional components are electrically bridged via the electronic component and/or the intermediary component.

2. The electronic package of claim 1, further comprising: a plurality of conductive pillars formed on the first side of the circuit structure and encapsulated by the encapsulation layer, wherein a top surface of each of the plurality of conductive pillars is exposed from the first surface.

3. The electronic package of claim 1, further comprising: a packaging layer formed on the second side of the circuit structure and encapsulating the plurality of functional components.

4. The electronic package of claim 1, further comprising: a plurality of conductive components disposed on the first surface of the encapsulation layer, the first passivation layer, and the second passivation layer, wherein the plurality of conductive components are electrically connected to the plurality of conductive vias.

5. The electronic package of claim 1, further comprising:
a wiring layer formed on the first surface of the encapsulation layer, the first passivation layer, and the second passivation layer; and
a plurality of conductive components disposed on the wiring layer.

6. The electronic package of claim 1, wherein the electronic component has an active surface and an inactive surface opposite to the active surface, and the electronic component is electrically connected to the circuit structure with the active surface of the electronic component facing the first side of the circuit structure.

7. The electronic package of claim 1, wherein the intermediary component is electrically connected to the circuit structure via the plurality of conductive vias.

8. The electronic package of claim 1, wherein the plurality of functional components are electrically connected to the circuit structure via a plurality of conductive bumps.

9. The electronic package of claim 1, wherein the electronic component and the intermediary component are recessed with respect to the first surface of the encapsulation layer so that a first concave portion and a second concave portion are formed.

10. The electronic package of claim 9, wherein the first concave portion and the second concave portion are filled with the first passivation layer and the second passivation layer, respectively.

11. A method of manufacturing an electronic package, comprising:
providing an electronic module, comprising: a circuit structure having a first side and a second side opposite to the first side; an electronic component disposed on the first side of the circuit structure; an intermediary component disposed on the first side of the circuit structure and having a plurality of conductive vias; an encapsulation layer having a first surface and a second surface opposite to the first surface and formed on the first side of the circuit structure via the second surface to encapsulate the electronic component and the intermediary component; and a plurality of functional components disposed on the second side of the circuit structure, wherein the plurality of functional components are electrically bridged via the electronic component and/or the intermediary component;
performing a thinning process on the electronic component and the intermediary component, wherein the electronic component and the intermediary component are recessed with respect to the first surface of the encapsulation layer to form a first concave portion and a second concave portion, respectively, and the plurality of conductive vias protrude from the second concave portion; and
forming a first passivation layer and a second passivation layer in the first concave portion and the second concave portion, respectively, wherein the first passivation layer, the second passivation layer, and a top surface of each of the plurality of conductive vias are exposed from the first surface.

12. The method of claim 11, wherein the thinning process comprises removing a portion of a material of the electronic component and a portion of a material of the intermediary component, by a wet etching process to form the first concave portion and the second concave portion, respectively.

13. The method of claim 11, wherein the first passivation layer and the second passivation layer are formed by filling the first concave portion and the second concave portion with a liquid adhesive to cover the electronic component and the intermediary component.

14. The method of claim 13, further comprising: performing a planarization process to remove a portion of the first passivation layer, a portion of the second passivation layer, and a portion of the encapsulation layer, wherein the first passivation layer, the second passivation layer, and the top surface of each of the plurality of conductive vias are flush with the first surface of the encapsulation layer.

15. The method of claim 11, wherein the electronic module further comprises a plurality of conductive pillars formed on the first side of the circuit structure and encapsulated by the encapsulation layer, and a top surface of each of the plurality of conductive pillars is exposed from the first surface.

16. The method of claim 11, wherein the electronic module further comprises a packaging layer formed on the second side of the circuit structure to encapsulate the plurality of functional components.

17. The method of claim 11, further comprising: forming a plurality of conductive components on the first surface of the encapsulation layer, the first passivation layer, and the second passivation layer, wherein the plurality of conductive components are electrically connected to the plurality of conductive vias.

18. The method of claim 11, further comprising:
forming a wiring layer on the first surface of the encapsulation layer, the first passivation layer, and the second passivation layer; and
forming a plurality of conductive components on the wiring layer.

19. The method of claim 11, wherein the electronic component has an active surface and an inactive surface opposite to the active surface, and the electronic component is electrically connected to the circuit structure with the active surface of the electronic component facing the first side of the circuit structure.

20. The method of claim 11, wherein the intermediary component is electrically connected to the circuit structure via the plurality of conductive vias.

21. The method of claim 11, wherein the plurality of functional components are electrically connected to the circuit structure via a plurality of conductive bumps.
